(19) United States
(12) Patent Application Publication
(10) Pub. No.: US 2005/0090044 A1
(43) Pub. Date: Apr. 28, 2005

(54) Epoxy resin compositions and semiconductor devices

(76) Inventors: Keiji Kayaba, Iwakura-shi (JP); Akihiro Tabata, Nagoya-shi (JP); Takafumi Otsu, Nagoya-shi (JP); Yoshiyuki Tsuji, Nagoya-shi (JP); Akio Oura, Nagoya-shi (JP)

Correspondence Address: SMITH, GAMBRELL & RUSSELL, LLP, 1850 M STREET, N.W., SUITE 800, WASHINGTON, DC, 20036, US

(21) Appl. No.: 10/490,659

(22) PCT Filed: Sep. 25, 2002
(86) PCT No.: PCT/JP02/09850

(30) Foreign Application Priority Data
Sep. 28, 2001 (JP) 2001-303427
Jan. 30, 2002 (JP) 2002-22563

(51) Int. Cl. C09J 1/00; H01L 21/48

(52) U.S. Cl. 438/127; 156/330

(57) ABSTRACT

(1) An epoxy resin composition comprising an epoxy resin of the tetramethylbisphenol F type, a curing agent, a filler and a silane coupling agent comprising an aminosilane coupling agent having primary amino group; (2) an epoxy resin composition comprising an epoxy resin of the tetramethylbisphenol F type, a curing agent comprising a specific phenol compound and a filler; and (3) an epoxy resin composition comprising an epoxy resin of the tetramethylbisphenol F type, a curing agent and a specific filler, are provided. The epoxy resin compositions exhibit excellent reliability such as the reliability on resistance to peeling off and to swelling during the reflow and an excellent filling property during molding and can be advantageously used for sealing electronic circuit members.

### TECHNICAL FIELD

The present invention relates to an epoxy resin composition which exhibits excellent reliability under the condition of the reflow, curing property and molding property and can be advantageously used for sealing semiconductor devices and a semiconductor device.

### BACKGROUND ART

As the process for sealing electronic circuit members such as semiconductor devices, sealing with resins such as phenol resins, silicone resins and epoxy resins have heretofore been proposed along with the hermetic sealing with metals and ceramics. In general, the resins used for the sealing are called the sealing resins. Among the sealing resins, epoxy resins are most frequently used from the standpoint of the balance of economy, productivity and physical properties. As the process for sealing with an epoxy resin, the process in which a composition is prepared by adding a curing agent and a filler to an epoxy resin, and a semiconductor device is set into a mold and sealed with the composition in accordance with the transfer molding, is widely conducted.

In the mounting of a package of semiconductor devices to a printed circuit board, the density is increasing and the process is being automated. In place of the heretofore used “insertion mounting process” in which lead pins are inserted into holes of the printed circuit board, the “surface mounting process” in which a package of semiconductor devices is attached to the surface of the substrate board by soldering is widely conducted. Due to this tendency, the structure of the package of semiconductor devices is changing from heretofore used DIP (the dual inline package) to FPP (the flat plastic package) which is thinner and more suitable for the surface mounting with a greater density.

In the surface mounting, in general, the mounting is conducted in accordance with the solder reflow. In this process, a package of semiconductor devices is placed on a substrate. The combination of the package and the substrate is exposed to a high temperature of 200° C. or higher so that solder placed on the substrate in advance is melted, and the package of semiconductors is fixed to the surface of the substrate. Since the entire package of semiconductor devices is exposed to a high temperature in this mounting process, problems arise in the case of a hygroscopic sealing resin in that peeling off takes place between the sealing resin and the semiconductor chip or between the sealing resin and the lead frame and that cracks are formed due to explosive expansion of the absorbed moisture during the solder reflow. In particular, the peeling off between the sealing resin and members such as chips, stages of lead frames and silver-plated portions of inner leads is a serious problem. Therefore, a sealing resin exhibiting the excellent sealing property has been desired, and the improvement in the adhesion with silver-plated portions is recently very important.

Due to the progress in the fine working, packages having a thickness of 2 mm or smaller such as TSOP, TQFP, LQFP and TQFP are being used as the major packages, and therefore the packages are more sensitive to the outside effects such as humidity and temperature. Reliabilities such as reliability under the condition of the reflow, reliability at high temperatures and reliability under moisture are becoming more important. In particular, recently, the reliability of packages having a thickness of 1 mm or smaller such as TSOP and TQFP under the condition of the reflow is required. In the case of thin packages, a problem arises in that the layer of the silver paste absorbs moisture and is peeled off at the interface of the silicon chip or the lead frame during the reflow and the bottom of the package is pushed down to cause swelling of the bottom portion of the package. Improvement in the resistance to swelling is required.

Moreover, lead-free solders which do not contain lead have been increasingly used recently from the standpoint of the protection of the environment. The lead-free solders have higher melting points, and the temperature of the reflow is elevated. Therefore, the reliability under the condition of the reflow is further required.

In general, it has been known that increasing the content of a filler in a sealing resin composition is effective for enhancing the reliability under the condition of the reflow. This effect is exhibited since the hygroscopic property is suppressed due to the decrease in the content of the resin in the sealing resin composition. However, simply increasing the content of the filler in the sealing resin composition decreases fluidity of the composition, and problems such as the insufficient filling of packages and the stage shift arise.

As the epoxy resin which can improve the reliability under the condition of the reflow and the fluidity, an epoxy resin composition containing an epoxy resin of the tetramethylbisphenol F type (Japanese Patent Application Laid-Open No. Heisei 6(1994)-345850) and an epoxy resin composition containing an epoxy resin of the tetramethylbisphenol F type as the epoxy resin, a phenol aralkyl resin as the curing agent and 25 to 93% by weight of a filler (Japanese Patent Application Laid-Open No. Heisei 8(19946)-134183) have been proposed. However, the effect exhibited by the above compositions is not sufficient although the desired effect can be found. A resin composition exhibiting more excellent reliability under the condition of the reflow and, in particular, more excellent reliability on the resistance to swelling of packages having a thickness of 1 mm or smaller is desired.

To improve the molding property and the resistance to formation of cracks in soldering, an epoxy resin composition containing as the curing agent a phenol compound which is a copolymer having a repeating unit of a derivative of biphenyl and a repeating unit of a derivative of xylene bonded to each other has been proposed (Japanese Patent Application Laid-Open No. 2000-106872). However, no descriptions can be found on the adhesion with silver plating or the resistance to swelling.

To improve the adhesion with gold plating, the use of an epoxy resin of the bisphenol F type and a secondary aminosilane coupling agent, a silane coupling agent having isocyanurate ring or a silane coupling agent having sulfide bond has been proposed (Japanese Patent Application Laid-Open No. 2002-97341). However, no descriptions can be found on the adhesion with silver plating or the resistance to swelling.

The present invention has been made under the above circumstances and has an object of providing an epoxy resin composition which exhibits excellent reliability under the condition of the reflow at higher temperatures and excellent properties during molding such as the excellent property for filling the package and the excellent curing property and a semiconductor device sealed with the epoxy resin composition.

### DISCLOSURE OF THE INVENTION

As the first aspect, the present invention provides an epoxy resin composition which comprises epoxy resin (A), curing agent (B), filler (C) and silane coupling agent (D), wherein epoxy resin (A) comprises epoxy resin (a) of a tetramethylbisphenol F type expressed by chemical formula (I) which will be shown later and silane coupling agent (D) comprises aminosilane coupling agent (d1) having primary amino group.

As the second aspect, the present invention provides an epoxy resin composition which comprises epoxy resin (A), curing agent (B) and filler (C), wherein epoxy resin (A) comprises epoxy resin (a) of a tetramethylbisphenol F type, and curing agent (B) comprises a phenol compound (b2) having repeating unit structures represented by formulae (III) and (IV) which will be shown later.

As the third aspect, the present invention provides an epoxy resin composition which comprises epoxy resin (A), curing agent (B) and filler (C), wherein epoxy resin (A) comprises epoxy resin (a) of a tetramethylbisphenol F type, a content of filler (C) is 80 to 95% by weight based on an amount of an entire resin composition, and filler (C) comprises 5 to 30% by weight of amorphous silica (c1) having a particle diameter in a range of 0.01 to 1.00 μm.

### THE MOST PREFERRED EMBODIMENT TO CARRY OUT THE INVENTION

The first aspect of the present invention will be described in the following.

The first aspect of the present invention is characterized in that epoxy resin (A) comprises as the essential component thereof epoxy resin (a) of the tetramethylbisphenol F type expressed by formula (I):

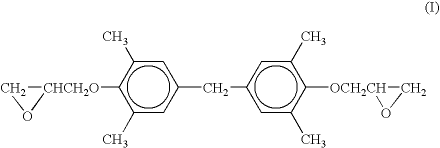

Due to epoxy resin of the tetramethylbisphenol F type expressed by formula (I) comprised in the epoxy resin, the resistance to swelling during the reflow is improved and, moreover, the effect of improving the molding property can be exhibited due to a decrease in viscosity.

Epoxy resins other than epoxy resin (a) expressed by formula (I) may be used in combination in accordance with the application. The other epoxy resin is not particularly limited as long as the epoxy resin is a compound having at least two epoxy groups in one molecule and may be a monomer, an oligomer or a polymer. Examples of the other epoxy resin include epoxy resins of the bisphenol F type having no alkyl substituents, epoxy resins of the cresol novolak type, epoxy resins of the phenol novolak type, epoxy resins of the biphenyl type such as 4,4′-bis(2,3-epoxypropoxy)biphenyl, 4,4′-bis(2,3-epoxypropoxy)-3,3′,5,5′-tetramethylbiphenyl, 4,4′-bis(2,3-epoxypropoxy)-3,3′,5,5′-tetraethylbiphenyl and 4,4′-bis(2,3-epoxypropoxy)-3,3′,5,5′-tetrabutylbiphenyl, epoxy resins of the phenol aralkyl type, epoxy resins of the naphthalene type, epoxy resins of the bisphenol A type, epoxy resins of the triphenol type, epoxy resins having the dicyclopentadiene skeleton structure, epoxy resins of the triphenylmethane type and halogenated epoxy resins. The other epoxy resins may be used singly or in combination of two or more.

When two or more epoxy resins are used in combination, it is preferable from the standpoint of the improvement in the resistance to swelling that the content of epoxy resin (a) expressed by formula (I) is 10% by weight or greater and more preferably 50% by weight or greater based on the amount of the entire epoxy resin (A) so that the effect of addition of epoxy resin (a) is more remarkably exhibited.

The amount of epoxy resin (A) is, in general, in the range of 0.5 to 10% by weight and preferably in the range of 1 to 6% by weight based on the amount of the entire epoxy resin composition.

Curing agent (B) in the first aspect of the present invention is not particularly limited as long as the epoxy resin is cured by the reaction with curing agent (B). Examples of curing agent (B) include novolak resins such as phenol novolak, cresol novolak and naphthol novolak, phenol aralkyl resins, phenol aralkyl resins having the biphenyl skeleton structure, phenol resins having the dicyclopentadiene skeleton structure, naphthol aralkyl resins, bisphenol compounds such as bisphenol A, acid anhydrides such as maleic anhydride, phthalic anhydride and pyromellitic anhydride, and aromatic amines such as meta-phenylenediamine, diaminodiphenylmethane and diaminodiphenylsulfone. The above curing agents may be used singly or in combination of two or more. It is preferable that curing agent (B) has a melt viscosity of 0.3 Pa.s or smaller and more preferably 0.1 Pa.s or smaller as expressed by the ICI viscosity (150° C.).

As curing agent (B), phenol aralkyl resin (b 1) represented by general formula (II): 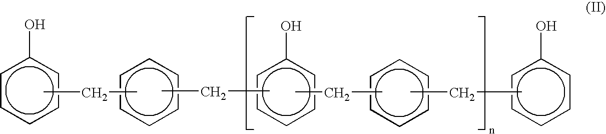
wherein n represents 0 or an integer of 1 or greater, is particularly preferable from the standpoint of the reliability under the condition of the reflow.

When two or more types of the curing agents are used in combination, it is preferable that the content of phenol aralkyl resin (b1) represented by general formula (II) is in the range of 10% by weight or greater and more preferably 20% by weight or greater based on the amount of entire curing agent (B).

The amount of curing agent (B) is, in general, in the range of 0.5 to 10% by weight and preferably in the range of 1 to 6% by weight based on the amount of the entire epoxy resin composition. As for the relative amounts of epoxy resin (A) and curing agent (B), it is preferable that the ratio of the amount by chemical equivalent of curing agent (B) to the amount by chemical equivalent of epoxy resin (A) is in the range of 0.5 to 1.5 and more preferably in the range of 0.6 to 1.3 from the standpoint of the mechanical properties and the resistance to moisture.

In the first aspect of the present invention, a curing catalyst may be used to accelerate the curing reaction between epoxy resin (A) and curing agent (B). The curing catalyst is not particularly limited as long as the curing catalyst accelerates the curing reaction. Examples of the curing catalyst include imidazole compounds such as 2-methylimidazole, 2,4-dimethylimidazole, 2-ethyl-4-methylimidazole, 2-phenylimidazole, 2-phenyl-4-methylimidazole and 2-heptadecylimidazole; tertiary amine compounds such as triethylamine, benzyldimethylamine, α-methylbenzyl-methylamine, 2-(dimethylaminomethyl)phenol, 2,4,6-tris(dimethylaminomethyl)phenol and 1,8-diazabicyclo(5,4,0)undecene-7; organometallic compounds such as zirconium tetramethoxide, zirconium tetrapropoxide, tetrakis(acetylacetonato)zirconium and tri(acetylacetonato)aluminum; and organic phosphine compounds such as triphenylphosphine, tetraphenylphosphonium tetraphenylborate, trimethylphosphine, triethylphosphine, tributylphosphine, tri(p-methylphenyl)phosphine and tri(nonylphenyl)phosphine. From the standpoint of the reliability and the molding property, organic phosphine compounds are preferable, and triphenylphosphine is more preferable among these compounds.

The above curing catalysts may be used singly or in combination of two or more. It is preferable that the amount of the curing catalyst is in the range of 0.1 to 10 parts by weight per 100 parts by weight of epoxy resin (A).

As filler (C) used in the first aspect of the present invention, inorganic fillers are preferable. Examples of the inorganic filler include metal oxides such as amorphous silica, crystalline silica, calcium arbonate, magnesium carbonate, alumina, magnesia, clay, talc, calcium ilicate, titanium oxide and antimony oxide; asbestos; glass fibers; and glass beads. Among these fillers, amorphous silica is preferable since amorphous silica exhibits a great effect of decreasing the coefficient of linear expansion and is effective for decreasing the stress. As for the shape of the filler, fillers having crushed shapes and spherical shapes are used, and fillers having spherical shapes are preferable from the standpoint of the fluidity.

The amorphous silica described above means, in general, amorphous silica having a true specific gravity of 2.3 or smaller. The amorphous silica can be produced in accordance with any conventional process. Various processes using various materials such as melting of crystalline silica, oxidation of metallic silicon and hydrolysis of alkoxysilanes can be used.

Among the amorphous silica, spherical fused silica produced by melting of quartz is particularly preferable. It is preferable that filler (C) comprises spherical fused silica in an amount of 90% by weight or more based on the amount of the entire filler (C).

The particle diameter and the distribution of the particle diameter of filler (C) are not particularly limited. From the standpoint of the fluidity and the decrease in burr during molding, it is preferable that the average particle diameter (the average diameter means the median diameter, hereinafter) is in the range of 5 to 30 μm. Two or more types of fillers having different average particle diameters or different distributions of the particle diameter may be used in combination.

Silane coupling agent (D) used in the first aspect of the present invention is characterized in that silane coupling agent comprises aminosilane coupling agent. (d1) having primary amino group as the essential component thereof Due to aminosilane coupling agent (d1) having primary amino group comprised in silane coupling agent (D), the reliability under the condition of the reflow, in particular, the reliability on the adhesion can be improved, and the effect of improving the curing property is also exhibited.

It is more preferable that silane coupling agent (D) comprises aminosilane coupling agent (d1) having primary amino group and silane coupling agent (d2) other than aminosilane coupling agent (d1) having primary amino group. Due to silane coupling agent (d2) other than aminosilane coupling agent (d1) having primary amino group comprised in silane coupling agent (D), the molding property is further improved. As silane coupling agent (d2) other than aminosilane coupling agent (d1) having primary amino group, silane coupling agent (d2) comprising at least one coupling agent selected from the group consisting of aminosilane coupling agents having no primary amino group but having secondary amino group and mercaptosilane coupling agents is preferable. Due to the above agent, the composition exhibiting more excellent molding property and adhesion can be obtained.

As for the relative amounts of aminosilane coupling agent (d1) and silane coupling agent (d2) in silane coupling agent (D), it is preferable that the ratio of the amounts by weight (d1)/(d2) is in the range of 3/97 to 97/3, more preferably in the range of 10/90 to 90/10 and most preferably in the range of 40/60 to 90/10.

Components (d1) and (d2) in silane coupling agent (D) may be added as a mixture prepared in advance or separately and may be used as a mixture with or a reaction product with other components in the resin composition prepared in advance.

Examples of aminosilane coupling agent (d1) having primary amino group include γ-aminopropyltrimethoxysilane, γ-aminopropyltriethoxysilane, N,β-(aminoethyl)-γ-aminopropyltrimethoxysilane, N-β-(aminoethyl)-γ-aminopropylmethyldimethoxysilane, N-β-(aminoethyl)-γ-aminopropyltriethylsilane, γ-aminopropylmethyldiethoxysilane and γ-aminopropylmethyldimethoxysilane. Among these compounds, γ-aminopropyltrimethoxysilane and γ-aminopropyltriethoxysilane are preferable from the standpoint of the reliability under the condition of the reflow.

Examples of silane coupling agent (d2) include compounds in which organic groups bonded to silicon atom are hydrocarbon groups and hydrocarbon groups having epoxy group, secondary amino group, tertiary amino group, (meth)acryloyl group or mercapto group, such as γ-glycidoxypropyltrimethoxysilane, γ-glycidoxypropylmethyldimethoxysilane, γ-(2,3-epoxycyclohexyl)propyltrimethoxysilane, γ-glycidoxypropyltrimethoxysilane, γ-(N-phenylamino)propyltrimethoxysilane, γ-(N-ethylamino)propylmethyltrimethoxysilane, γ-methacryloxypropyltrimethoxysilane, γ-methacryloxypropylmethyldimethoxysilane, γ-mercaptopropyltrimethoxysilane and γ-mercaptopropylmethyldimethoxysilane

Examples of the aminosilane coupling agent having no primary amino group but having secondary amino group include γ-(N-phenylamino)propyltrimethoxysilane, γ-(N-phenylamino)propylmethyldimethoxysilane, γ-(N-methylamino)propyltrimethoxysilane, γ-(N-methylamino)propylmethyldimethoxysilane, γ-(N-ethylamino)propyltrimethoxysilane and γ-(N-ethylamino)propylmethyldimethoxysilane. From the standpoint of the reliability on the resistance to moisture and the fluidity, γ-(N-phenylamino)propyltrimethoxysilane is preferable.

Examples of the mercaptosilane coupling agent include γ-mercaptopropyltrimethoxysilane, γ-mercaptopropyltriethoxysilane and γ-mercaptopropylmethyldimethoxysilane.

As for the content of silane coupling agent (D), it is preferable that the epoxy resin composition comprises silane coupling agent (D) in an amount of 0.1 to 2% by weight based on the amount of the entire epoxy resin composition from the standpoint of the fluidity and the filling property.

In the first aspect of the present invention, bromine compounds may be added to improve the flame retarding property although this is not the essential component. The bromine compound is not particularly limited as long as the compound is conventionally added to epoxy resin compositions as the flame retardant. Examples of the bromine compound include brominated epoxy resins such as brominated epoxy resins of the bisphenol A type and brominated epoxy resins of the phenol novolak type, brominated polycarbonate resins, brominated polystyrene resins, brominated polyphenylene oxide resins, tetrabromobisphenol A and decabromodiphenyl ether. Among these compounds, brominated epoxy resins such as brominated epoxy resins of the bisphenol A type and brominated epoxy resins of the phenol novolak type are preferable from the standpoint of the molding property.

In the first aspect of the present invention, antimony compounds may be added to improve the flame retarding property although this is not the essential component. The antimony compound is not particularly limited as long as the compound is conventionally added to epoxy resin compositions for sealing semiconductors as the auxiliary flame retardant, and conventional antimony compounds can be used. Examples of the antimony compound include antimony trioxide, antimony tetraoxide and antimony pentaoxide.

When the flame retardant and the auxiliary flame retardant are added, from the standpoint of the easiness of disposal of waste materials formed from the epoxy resin composition and the reliability of the semiconductor device, it is preferable that the contents of halogen atom and antimony atom are each 0.2% by weight or smaller, and it is more preferable that halogen atom and antimony atom are substantially absent.

Where desired, the epoxy resin composition of the first aspect of the present invention may further comprise the following additives: various coloring agents and various pigments such as carbon black and iron oxides; various elastomers such as silicone rubber, olefin-based copolymers, modified nitrile rubbers and modified polybutadiene rubbers; various thermoplastic resins such as silicone oils and polyethylene; surfactants such as fluorine-based surfactants and silicone-based surfactants; various mold-releasing agents such as long chain fatty acids, metal salts of long chain fatty acids, esters of long chain fatty acids, amides of long chain fatty acids and paraffin wax; ion scavengers such as hydrotalcite; and crosslinking agents such as organic peroxides.

The second aspect of the present invention will be described in the following.

As epoxy resin (A), the same epoxy resins as those described for the first aspect of the present invention can be used. Epoxy resin (A) comprises as the essential component thereof epoxy resin (a) of the tetramethylbisphenol F type expressed by formula (1). Due to the above epoxy resin comprised in epoxy resin (A), the epoxy resin composition exhibiting excellent resistance to swelling during the reflow, adhesion with silver plating and molding property can be obtained. The content of the above epoxy resin is the same as that described for the first aspect of the present invention. Other epoxy resins can be used in combination in the same manner as that described for the first aspect of the present invention.

In the second aspect of the present invention, as the essential component, phenol compound (b2) having a repeating unit structure represented by formula (III): 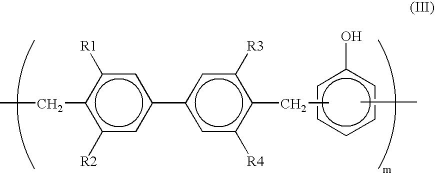
and a repeating unit structure represented by formula (IV): 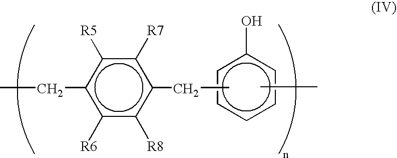
can be used as curing agent (B) from the standpoint of further improvements in adhesion and the resistance to formation of cracks. In formula (III), R₁ to R₄ represent hydrogen atom or methyl group, and m represents an integer of 1 or greater. In formula (IV), R₅ to R₈ represent hydrogen atom or methyl group, and n represents an integer of 1 or greater.

Due to the use of the phenol compound having repeating unit structures represented by formulae (III) and (IV), the adhesion of the sealing resin and the resistance to formation of cracks are remarkably improved.

The phenol compound having repeating unit structures represented by formulae (III) and (IV) is a copolymer in which the repeating unit structure of a biphenyl derivative represented by formula (III) and the repeating unit structure of a xylene derivative represented by formula (IV) are bonded to each other. As the copolymer, random copolymers in which these repeating unit structures are randomly bonded to each other are preferable. The process for producing the random copolymer is not particularly limited, and the random copolymer can be produced in accordance with a conventional process for producing phenol resins. It is preferable that the ratio of the amount by mole of the repeating unit structure of a biphenyl derivative represented by formula (III) to the amount by mole of the repeating unit structure of a xylene derivative represented by formula (IV) is in the range of 10:90 to 90:1 and more preferably in the range of 30:70 to 70:30. It is most preferable that the amounts by mole of the two structures are approximately the same, i.e., the above ratio is in the range of 45:55 to 55:45. It is preferable that the hydroxyl equivalent of the random copolymer is in the range of about 180 to 200. The ends of the polymer may be capped with any compound, and it is preferable that the ends are capped with phenol.

Due to the use of phenol-based compound (b2) having the repeating unit structures represented by formulae (III) and (IV), the adhesion is improved from that of the polymer having the repeating unit represented by formula (III) alone (a phenol aralkyl resin having biphenyl).

Due to the use of phenol-based compound (b2) having the repeating unit structures represented by formulae (III) and (IV), the resistance to formation of cracks is improved from that of the polymer having the repeating unit represented by formula (IV) alone (phenol aralkyl resin (b 1)).

From the standpoint of the fluidity, it is preferable that the viscosity of phenol-based compound (b2) having the repeating unit structures represented by formulae (III) and (IV) is 0.2 Pa.s or smaller and more preferably 0.1 Pa.s or smaller as expressed by the ICI viscosity at 150° C.

The amount of curing agent (B) is, in general, in the range of 0.5 to 10% by weight and preferably in the range of 1 to 6% by weight based on the amount of the entire epoxy resin composition. As for the relative amounts of epoxy resin (A) and curing agent (B), it is preferable that the ratio of the amount by chemical equivalent of curing agent (B) to the amount by chemical equivalent of epoxy resin (A) is in the range of O.5 to 1.5 and more preferably in the range of 0.6 to 1.3 from the standpoint of the mechanical properties and the resistance to moisture.

Due to the combined use of epoxy resin (a) of the tetramethylbisphenol F type expressed by formula (I) and phenol-based compound (b2) having the repeating unit structures represented by formulae (III) and (IV), the epoxy resin composition exhibiting excellent resistance to swelling during the reflow, adhesion with silver plating and molding property can be obtained.

As filler (C) in the second aspect of the present invention, the same fillers as those described for the first aspect of the present invention can be used. Preferable embodiments are the same as those described for the first aspect of the present invention.

Where desired, in the same manner as that described for the first aspect of the present invention, the epoxy resin composition of the second aspect of the present invention may further comprise the following additives: silane coupling agents, curing catalysts, flame retardants, various coloring agents and various pigments such as carbon black and iron oxides; various elastomers such as silicone rubber, olefin-based copolymers, modified nitrile rubbers and modified polybutadiene rubbers; various thermoplastic resins such as silicone oils and polyethylene; surfactants such as fluorine-based surfactants and silicone-based surfactants; various mold-releasing agents such as long chain fatty acids, metal salts of long chain fatty acids, esters of long chain fatty acids, amides of long chain fatty acids and paraffin wax; ion scavengers such as hydrotalcite; and crosslinking agents such as organic peroxides.

The third aspect of the present invention will be described in the following.

As epoxy resin (A), the same epoxy resins as those described for the first aspect of the present invention can be used. Epoxy resin (A) comprises as the essential component thereof epoxy resin (a) of the tetramethylbisphenol F type expressed by formula (I). The content of the above epoxy resin is the same as that described for the first aspect of the present invention. Other epoxy resins can be used in combination in the same manner as that described for the first aspect of the present invention.

As curing agent (B), the same curing agents as those described for the first aspect of the present invention can be used. Preferable embodiments are the same as those described for the first aspect of the present invention.

Examples of filler (C) in the third aspect of the present invention include metal oxides such as amorphous silica, crystalline silica, calcium carbonate, magnesium carbonate, alumina, magnesia, clay, talc, calcium silicate, titanium oxide and antimony oxide; asbestos; glass fibers; and glass beads. Among these fillers, amorphous silica is preferable since amorphous silica exhibits a great effect of decreasing the coefficient of linear expansion and is effective for decreasing the stress. As for the shape of the filler, fillers having shapes obtained by crushing and spherical shapes are used. From the standpoint of the improvement in the fluidity, shapes having a ratio of the length of the major axis a to the length of the minor axis b (a/b) of 5 or smaller are preferable, and shapes having a/b of 2 or smaller are more preferable.

As for the length of the major axis a and the length of the minor axis b of the shape of the particle of filler (C) in the third aspect of the present invention, the length of the major axis a means the diameter of a circumcircle of a particle, and the length of the minor axis b means the minimum distance between parallel lines tangent to the contour of a particle. The length of the major axis a and the length of the minor axis b can be measured, for example, in accordance with the method in which the length of the major axis a and the length of the minor axis b of a plurality of silica particles are measured using a microscopic picture of silica, and the average of the obtained values is obtained; or in accordance with the method in which an epoxy resin for sealing semiconductors containing silica is transfer molded, the obtained molded article is cut by a diamond cutter, the section is polished, a microscopic picture of the section is taken using a scanning electron microscope, the length of the major axis a and the length of the minor axis b are measured using a plurality of silica particles having the shapes and the sizes which are the same with or different from each other, and the average of the obtained values is obtained.

The particle diameter and the distribution of the particle diameter of filler (C) are not particularly limited. From the standpoint of the fluidity and the decrease in the amount of burr in molding, it is preferable that the median diameter is in the range of 5 to 30 μm. The median diameter means the diameter obtained as follows: the distribution of the particle diameter is measured, for example, using a meter of the laser diffraction type for measuring the distribution of the particle diameter; the amount by weight of each incremental fraction in the distribution is accumulated from the fraction having the smallest diameter to fractions having greater diameters; and, when the accumulated amount by weight reaches 50% of the amount by weight of the entire particles, the diameter of the last fraction is defined as the median diameter. Two or more fillers having different median diameters or different distributions of the particle diameter may be used in combination.

In the third aspect of the present invention, it is important that filler (C) comprises 5 to 30% by weight of amorphous silica (c1) having a particle diameter in the range of 0.01 to 1.00 μm Due to this composition, the content of the filler in the entire resin composition can be increased, and the improvement in the resistance to the reflow and the improvement in the molding property such as the decrease in the stage shift can be simultaneously achieved.

When the content of amorphous silica (c1) having a particle diameter in the range of 0.01 to 1.00 μm in filler (C) is smaller than 5% by weight or exceeds 30% by weight, the content of filler (C) in the resin composition cannot be increased, and the object of the present invention cannot be achieved as the result. It is preferable that filler (C) comprises 5 to 20% by weight of amorphous silica (c1).

As for the shape of amorphous silica having a particle diameter in the range of 0.01 to 1.00 μm, silica having a crushed shape or spherical shapes is used, and silica having a spherical shape is preferable from the standpoint of the fluidity. As for the sphericity, it is preferable that the ratio of the length of the major axis a to the length of the minor axis b (a/b) is 2 or smaller and more preferably 1.3 or smaller, i.e., in the range of 1 to 1.3. From the standpoint of the fluidity, it is preferable that the fraction of spherical silica having the ratio of the length of the major axis a to the length of the minor axis b (a/b) of 2 or smaller is 90% by weight or greater based on the amount of the entire amorphous silica.

Amorphous silica (c1) can be prepared in accordance with any conventional processes. Examples of the process include synthetic processes using various materials such as the process in which melting and classification of crystalline silica are repeated a plurality of times; the process in which powder of metallic silicon is placed into a furnace from the top of the furnace while oxygen is introduced to allow the self-combustion at a high temperature to proceed, and powder of silicon oxide is obtained by cooling at the bottom of the furnace; and the process in which an alkoxysilane is hydrolyzed. Among the above processes, the process of the self-combustion of metallic silicon at a high temperature in the presence of oxygen is preferable since fluctuation in the size of the particles is small, and truly spherical particles can be obtained.

In the third aspect of the present invention, it is necessary that the content of filler (C) exceed 80% by weight and be 95% by weight or smaller based on the amount of the entire resin composition. It is preferable that the content of filler (C) is in the range of 85 to 93% by weight. When the content of filler (C) is smaller than 80% by weight, the decrease in the absorption of moisture of the sealing resin and the increase in the modulus are insufficient, and the sufficient reliability under the condition of the reflow cannot be achieved to the required severe level. While the reliability under the condition of the reflow deteriorates when the content of filler (C) is smaller than 80% by weight, the epoxy resin composition exhibiting the improved resistance to swelling can be obtained when content of filler (C) exceeds 85% by weight. On the other hand, when the content of filler (C) exceeds 95% by weight, the stage shift and the incomplete filling of a package arise due to an increase in the viscosity, and the fraction of defect products increases.

When the content of filler (C) in the entire resin composition is increased, the flame retarding property is improved, and the flame retarding property can be maintained without the use of flame retardants which are used heretofore. Due to this effect, the addition of halogen components used heretofore as the flame retardant of a component of the sealing material becomes unnecessary, and the product is advantageous from the standpoint of the environmental protection.

In the third aspect of the present invention, the same additives as those used for the first aspect of the present invention can be used as the other additives. Examples of such additives include silane coupling agents, curing catalysts, various coloring agents and various pigments such as carbon black and iron oxides; various elastomers such as silicone rubber, olefin-based copolymers, modified nitrile rubbers and modified polybutadiene rubbers; various thermoplastic resins such as silicone oils and polyethylene; surfactants such as fluorine-based surfactants and silicone-based surfactants; various mold-releasing agents such as long chain fatty acids, metal salts of long chain fatty acids, esters of long chain fatty acids, amides of long chain fatty acids and paraffin wax; ion scavengers such as hydrotalcite; and crosslinking agents such as organic peroxides.

It is preferable that the epoxy resin composition of the present invention is produced by melt mixing the above components. For example, after the various raw materials are mixed using a conventional process such as the process using a mixer, the epoxy resin composition can be produced by melt mixing the obtained mixture in accordance with a conventional process such as the process using a Banbury mixer, a kneader, rolls, a single screw extruder, a twin-screw extruder or a cokneader. The temperature of the melt mixing is, in general, in the range of 70 to 150° C.

The epoxy resin composition of the present invention can be used in the form of powder obtained by melting in mixing under heating, followed by cooling and pulverizing; in the form of tablets obtained by pressing the powder to form the tablets; in the form of tablets obtained by melt mixing under heating, followed by solidification by cooling in molds; and in the form of pellets obtained by melt mixing under heating, followed by extrusion and cutting.

The epoxy resin composition of the present invention in the above form is used for sealing semiconductor devices in the production of semiconductor devices. The epoxy resin composition of the present invention is molded over a member having a semiconductor fixed to a substrate, for example, in accordance with the transfer molding, the injection molding or the casting at 120 to 250° C. and preferably at 150 to 200° C., and a semiconductor device sealed with the cured product of the epoxy resin composition can be produced. Where necessary, an additional treatment by heating, for example, at 150 to 200° C. for 2 to 16 hours, may be conducted.

### EXAMPLES

The present invention will be described more specifically with reference to examples in the following. However, the present invention is not limited to the examples. In the examples, “%” means “% by weight”.

### Examples 1 to 35 and Comparative Example 1 to 12

For the first aspect of the present invention, components shown in Table 1 were used in relative amounts (relative amounts by weight) shown in Tables 2 and 3. For the second aspect of the present invention, components shown in Table 1 were used in relative amounts (relative amounts by weight) shown in Tables 4 and 5. For the third aspect of the present invention, filler (C) shown in Table 6 was used, and components shown in Table 7 were used in relative amounts (relative amounts by weight) shown in Tables 8 to 10. The components were dry blended by a mixer, mixed under heating for 5 minutes by mixing rolls while the temperature of the surface of the rolls was adjusted at 90° C., cooled and pulverized, and epoxy resin compositions for sealing semiconductor devices were obtained.

<Evaluation of the Resistance to Swelling (the Reliability Under the Condition of the Reflow>

A resin composition obtained above was molded into a package using a mold for 144 pin TQFP (the outer size: 20 mm×2O mm×1.0 mm; the material of the frame: copper) by a transfer molding machine at a mold temperature of 175° C. for a curing time of 1 minute. As the chip for the evaluation, a chip having a size of 8 mm×8 mm×0.3 mm and having a mock device coated with a film of silicon nitride on the surface was used.

Ten packages of 144 pin TQFP obtained by the molding described above were post-cured under the condition of 180° C. for 6 hours, and the thickness I (em) of the packages at the central portion was measured by a micrometer. The post-cured packages were humidified at 850° C. under a relative humidity of 60% for 24 hours and then treated by heating in an IR reflow oven at the maximum temperature of 260° C. The temperature profile of the reflow oven was as follows: in the region of 150 to 200° C. for 60 to 100 seconds; temperature elevation in the region of 200 to 260° C. at a rate of 1.5 to 2.5° C./sec; in the region of 255 to 265° C., which was the maximum temperature, for 10 to 20 seconds; and temperature lowering in a region of 260 to 200° C. at a rate of 1.5 to 2.5° C./sec.

Five seconds after the packages were taken out of the oven, the thickness II (μm) of the packages at the central portion was measured by a micrometer. The value of (the thickness I−the thickness II) was calculated with respect to 10 packages, and the average of the obtained ten values was used as the “swelling” (μm). A smaller swelling is desirable. A swelling of 80 μm or smaller is more desirable.

For the evaluation in the third aspect of the present invention, the packages were humidified in the condition of a temperature of 30° C., a relative humidity of 60% and a time of 168 hours.

<Evaluation of the Curing Property>

A disk having a diameter of 5 cm and a thickness of 3.3 mm was prepared in accordance with the low pressure transfer molding at a temperature of a mold of 175° C. at the surface under a pressure of transfer of 30 kg/cm², and the hardness in the hot condition (Barcol hardness) was measured. The curing time passed before the hardness in the hot condition exceeded 60 was used as the curing time (sec).

<Fraction of Defective Adhesion>

Twenty packages of 144 pin TQFP were prepared in accordance with the same procedures as those conducted for the evaluation of the swelling and post-cured at 180° C. for 6 hours. The post-cured packages were humidified at 85° C. under a relative humidity of 60% for 24 hours and then treated by heating in an IR reflow oven at the maximum temperature of 260° C. The temperature profile of the reflow oven was as follows: in the region of 150 to 200° C. for 60 to 100 seconds; temperature elevation in the region of 200 to 260° C. at a rate of 1.5 to 2.5° C./sec; in the region of 255 to 265° C., which was the maximum temperature, for 10 to 20 seconds; and temperature lowering in the region of 260 to 200° C. at a rate of 1.5 to 2.5° C./sec.

Using the resultant packages, the conditions of peeling off at the silver-plated portion of the lead frame, the face of the chip and the back face of the stage were observed by an ultrasonic defectoscope (manufactured by HITACHI KENKI Co., Ltd.; “MI-SCOPE 10”). The number of packages having the peeling off at each of the above portions was recorded.

<Fraction of the Defective Resistance to Formation of Cracks>

Twenty packages of 144 pin TQFP were prepared in accordance with the same procedures as those conducted for the evaluation of the swelling and post-cured at 180° C. for 6 hours. The post-cured packages were humidified at 85° C. under a relative humidity of 60% for 24 hours and then treated by heating in an IR reflow oven at the maximum temperature of 260° C. The temperature profile of the reflow oven was as follows: in the region of 150 to 200° C. for 60 to 100 seconds; temperature elevation in the region of 200 to 260° C. at a rate of 1.5 to 2.5° C./sec; in the region of 255 to 265° C., which was the maximum temperature, for 10 to 20 seconds; and temperature lowering in the region of 260 to 200° C. at a rate of 1.5 to 2.5° C./sec.

The outside of the packages was visually observed, and the number of packages having defects was recorded.

<Evaluation of the Molding Property (the Property for Filling a Package and the Stage Shift>)

Ten packages of 144 pin TQFP prepared in accordance with the same procedures as those described above were visually observed after being prepared by the molding and after being cut to expose a section using a microscope of 20 times magnification, and the presence or the absence of the stage shift and the incomplete filling was examined. Excluding defect packages having the stage shift or the incomplete filling, the number of packages in good condition was obtained. With respect to the stage shift, a package was evaluated as defective when the gap between the gate portion of the package and the vent portion was 100 μm or greater.

In the third aspect of the present invention, the evaluation was conducted as follows: with respect to the stage shift, the gap between the gate portion of the package and the vent portion was measured; the average of the values obtained by the measurement on the ten packages was used as the “stage shift”; and the result of the evaluation was expressed as “passed” when the obtained value was smaller than 50 μm and as “failed” when the obtained value was 50 μm or greater. The results of the evaluations are shown in Tables 2 and 3.

TABLE 1

| Type | | Raw material |
|---|---|---|
| Filler | | spherical fused silica having an average particle diameter of 22 μm |
| Silane coupling | 1 | N-phenylaminopropyltrimethoxysilane, formula (V) |
| agent | 2 | γ-aminopropyltrimethoxysilane, formula (VI) |
| | 3 | N-β-(aminoethyl)-γ-aminopropyltrimethoxysilane, formula (VII) |
| | 4 | γ-glycidoxypropyltrimethoxysilane, formula (VIII) |
| | 5 | γ-mercaptopropyltrimethoxysilane, formula (IX) |
| Epoxy resin | 1 | epoxy resin of tetramethylbisphenol F type, formula (I) |
| | 2 | epoxy resin of tetramethylbiphenyl type, (4,4′-bis(2,3-epoxy-propoxy)-3,3′,5,5′-tetramethylbiphenyl) |
| | 3 | epoxy resin of bisphenol F type, formula (X) |
| | 4 | epoxy resin of o-cresol novolak type (epoxy equivalent: 194) |
| Curing agent | 1 | phenol aralkyl resin, formula (XI) (hydroxyl equivalent: 175; ICI viscosity at 150° C.: 0.09 Pa-s) |
| | 2 | phenol novolak resin, formula (XII) (hydroxyl equivalent: 107; ICI viscosity at 150° C.: 0.2 Pa-s) |
| | 3 | phenol-based compound obtained by random copolymerization of repeating units represented by formulae |
| | | (III) and (IV) in relative amounts by mole of 1:1 (hydroxyl equivalent: 187; ICI viscosity at 150° C.: 0.075 |
| | | Pa-s; R1 to R8 represent hydrogen atom) |
| | 4 | phenol-based compound, formula (XIII) (hydroxyl equivalent: 203; ICI viscosity at 150° C.: 0.075 Pa-s) |
| Curing accelerator | | triphenylphosphine |
| mold-releasing | | carnauba wax |
| agent | | |
| Coloring agent | | carbon black |

Formulae in Table 1 (In the following formulae (XI), (XII), (XIII), n represents 0 or an integer of 1 or greater)

| | |
|---|---|
| 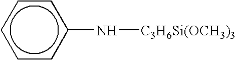 | (V) |
| NH₂—C₃H₆Si(OCH₃)₃ | (VI) |
| NH₂—C₂H₄—NH—C₃H₆Si(OCH₃)₃ | (VII) |
| 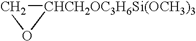 | (VIII) |
| HS(CH₂)₃Si(OCH₃)₃ | (IX) |
| 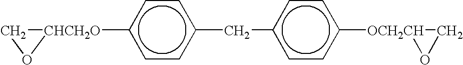 | (X) |
| 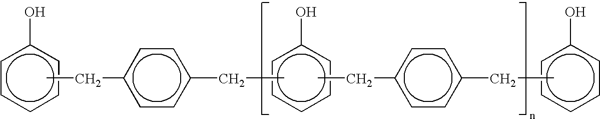 | (XI) |
| 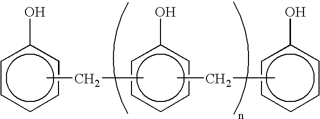 | (XII) |
| 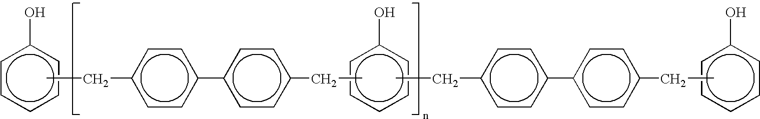 | (XIII) |

TABLE 2

| | | Example | | | | | | | | | | |
|---|---|---|---|---|---|---|---|---|---|---|---|---|
| | | 1 | 2 | 3 | 4 | 5 | 6 | 7 | 8 | 9 | 10 | Note |
| Filler (% by wt) | | 91 | 92 | 91 | 91 | 91 | 91 | 91 | 91 | 91 | 91 | |
| Silane coupling agent | 1 | 0.4 | 0.4 | 0.4 | 0.25 | 0.1 | 0.4 | | | | 0.4 | #1 |
| (% by wt) | 2 | 0.1 | 0.1 | 0.1 | 0.25 | 0.4 | 0.1 | 0.25 | 0.15 | 0.25 | | #2 |
| | 3 | — | — | — | — | — | — | — | — | — | 0.1 | #3 |
| | 4 | — | — | — | — | — | — | — | — | 0.25 | | #4 |
| | 5 | — | — | — | — | — | — | 0.25 | 0.35 | | — | #5 |
| Epoxy resin | 1 | 4.6 | 4.0 | 2.3 | 4.6 | 4.6 | 4.6 | 4.6 | 4.6 | 4.6 | 4.6 | *1 |
| (% by wt) | 2 | — | — | 2.3 | — | — | — | — | — | — | — | *2 |
| | 3 | — | — | — | — | — | — | — | — | — | — | *3 |
| | 4 | — | — | — | — | — | — | — | — | — | — | *4 |
| Curing agent | 1 | 3.3 | 2.9 | 3.3 | 3.3 | 3.3 | — | 3.3 | 3.3 | 3.3 | 3.3 | *5 |
| (% by wt) | 2 | — | — | — | — | — | 3.3 | | | | — | *6 |
| Curing accelerator | | 0.1 | 0.1 | 0.1 | 0.1 | 0.1 | 0.1 | 0.1 | 0.1 | 0.1 | 0.1 | |
| (% by wt) | | | | | | | | | | | | |
| Mold-releasing agent | | 0.2 | 0.2 | 0.2 | 0.2 | 0.2 | 0.2 | 0.2 | 0.2 | 0.2 | 0.2 | |
| (% by wt) | | | | | | | | | | | | |
| Carbon black (% by wt) | | 0.3 | 0.3 | 0.3 | 0.3 | 0.3 | 0.3 | 0.3 | 0.3 | 0.3 | 0.3 | |
| Resistance to swelling | | 62 | 51 | 65 | 63 | 60 | 68 | 60 | 60 | 68 | 63 | |
| (μm) | | | | | | | | | | | | |
| Curing property (sec) | | 40 | 35 | 40 | 35 | 30 | 45 | 30 | 40 | 49 | 40 | |
| Fraction of defective | | 0 | 0 | 0 | 0 | 0 | 0 | 0 | 0 | 0 | 0 | |
| adhesion | | | | | | | | | | | | |
| (with silver plating) | | | | | | | | | | | | |
| Fraction of defective | | 0 | 0 | 0 | 0 | 0 | 0 | 0 | 0 | 0 | 0 | |
| adhesion | | | | | | | | | | | | |
| (with chip) | | | | | | | | | | | | |
| Fraction of defective | | 0 | 0 | 0 | 0 | 0 | 0 | 0 | 0 | 0 | 0 | |
| adhesion | | | | | | | | | | | | |
| (with back face of stage) | | | | | | | | | | | | |
| Molding property | | 10 | 10 | 10 | 10 | 10 | 10 | 10 | 10 | 9 | 10 | |
| (property for filling | | | | | | | | | | | | |
| package) | | | | | | | | | | | | |
| | | 100.0 | 100.0 | 100.0 | 100.0 | 100.0 | 100.0 | 100.0 | 100.0 | 100.0 | 92.10 | |

Notes
#1: Secondary
#2: Primary
#3: Primary + secondary
#4: Ep
#5: Mercapto
*1: Epoxy resin of the tetramethylbisphenol F type
*2: Epoxy resin of the tetramethylbiphenyl type
*3: Epoxy resin of the bisphenol F type represented by formula (IX)
*4: Epoxy resin of the o-cresol novolak type (epoxy equivalent: 194)
*5: Phenol aralkyl resin represented by formula (III)
*6: PN

TABLE 3

| | | Comparative Example | | | | | |
|---|---|---|---|---|---|---|---|
| | | 1 | 2 | 3 | 4 | 5 | Note |
| Filler (% by wt) | | 91 | 91 | 91 | 91 | 91 | |
| Silane coupling agent | 1 | 0.5 | — | 0.4 | 0.4 | 0.25 | #1 |
| (% by wt) | 2 | — | — | 0.1 | 0.1 | 0.25 | #2 |
| | 3 | — | — | — | — | — | #3 |
| | 4 | — | 0.5 | — | — | — | #4 |
| | 5 | | | | | | #5 |
| Epoxy resin | 1 | 4.6 | 4.6 | — | — | — | *1 |
| (% by wt) | 2 | — | — | 4.6 | — | 1.0 | *2 |
| | 3 | — | — | — | 4.6 | — | *3 |
| | 4 | — | — | — | — | 3.6 | *4 |
| Curing agent | 1 | 3.3 | 3.3 | 3.3 | 3.3 | 3.3 | *5 |
| (% by wt) | 2 | — | — | — | — | — | *6 |
| Curing accelerator | | 0.1 | 0.1 | 0.1 | 0.1 | 0.1 | |
| (% by wt) | | | | | | | |
| Mold-releasing agent | | 0.2 | 0.2 | 0.2 | 0.2 | 0.2 | |
| (% by wt) | | | | | | | |
| Carbon black (% by wt) | | 0.3 | 0.3 | 0.3 | 0.3 | 0.3 | |
| Resistance to swelling (μm) | | 60 | 87 | 91 | 55 | 99 | |
| Curing property (sec) | | 65 | 70 | 45 | 35 | 35 | |
| Fraction of defective | | 0 | 0 | 0 | 0 | 20 | |
| adhesion | | | | | | | |
| (with silver plating) | | | | | | | |
| Fraction of defective | | 5 | 0 | 0 | 12 | 20 | |
| adhesion | | | | | | | |
| (with chip) | | | | | | | |
| Fraction of defective | | 5 | 0 | 0 | 0 | 20 | |
| adhesion | | | | | | | |
| (with back face of stage) | | | | | | | |
| Molding property | | 10 | 10 | 10 | 10 | 0 | |
| (property for filling | | | | | | | |
| package) | | | | | | | |
| | | 100.0 | 100.0 | 100.0 | 100.0 | 100.0 | |

Notes
#1: Secondary
#2: Primary
#3: Primary + secondary
#4: Ep
#5: Mercapto
*1: Epoxy resin of the tetramethylbisphenol F type
*2: Epoxy resin of the tetramethylbiphenyl type
*3: Epoxy resin of the bisphenol F type represented by formula (IX)
*4: Epoxy resin of the o-cresol novolak type (epoxy equivalent: 194)
*5: Phenol aralkyl resin represented by formula (III)
*6: PN

As shown in Tables 2 and 3, the curing property or the adhesion during the reflow was insufficient when the aminosilane coupling agent having primary amino group was not used. The resistance to swelling or the adhesion was insufficient when epoxy resin (a) of the tetramethylbisphenol F type expressed by formula (I) was not used as the epoxy resin. In contrast, the epoxy resin compositions of the first aspect of the present invention exhibited excellent adhesion during the reflow, resistance to swelling, property for filling a package and curing property.

The results of the evaluations are shown in Tables 4 and 5.

TABLE 4

| | | Example | | | | | | | | | |
|---|---|---|---|---|---|---|---|---|---|---|---|
| | | 11 | 12 | 13 | 14 | 15 | 16 | 17 | 18 | 19 | Note |
| Filler (% by wt) | | 90.0 | 92.0 | 90.0 | 90.0 | 90.0 | 90.0 | 90.0 | 90.0 | 90.0 | |
| Silane coupling agent | 1 | 0.4 | 0.4 | 0.4 | 0.25 | 0.1 | 0.4 | 0.4 | 0.4 | 0.4 | #1 |
| (% by wt) | 2 | 0.1 | 0.1 | 0.1 | 0.25 | 0.4 | 0.1 | 0.1 | 0.1 | 0.1 | #2 |
| | 3 | — | — | — | — | — | — | — | — | — | #3 |
| | 4 | — | — | — | — | — | — | — | — | — | #4 |
| | 5 | — | — | — | — | — | — | — | — | — | #5 |
| Epoxy resin | 1 | 4.8 | 3.7 | 2.4 | 4.8 | 4.8 | 4.8 | 5.2 | 4.4 | 4.8 | *1 |
| (% by wt) | 2 | — | — | 2.4 | — | — | — | — | — | — | *2 |
| | 3 | — | — | — | — | — | — | — | — | — | *3 |
| | 4 | — | — | — | — | — | — | — | — | — | *4 |
| Curing agent | 1 | — | — | — | — | — | 4.1 | — | — | 2.0 | *5 |
| (% by wt) | 2 | — | — | — | — | — | — | 3.7 | — | — | *6 |
| | 3 | 4.1 | 3.2 | 4.1 | 4.1 | 4.1 | — | — | — | — | *7 |
| | 4 | — | — | — | — | — | — | — | 4.5 | 2.1 | *8 |
| Curing accelerator | | 0.1 | 0.1 | 0.1 | 0.1 | 0.1 | 0.1 | 0.1 | 0.1 | 0.1 | |
| (% by wt) | | | | | | | | | | | |
| Mold-releasing agent | | 0.2 | 0.2 | 0.2 | 0.2 | 0.2 | 0.2 | 0.2 | 0.2 | 0.2 | |
| (% by wt) | | | | | | | | | | | |
| Carbon black (% by wt) | | 0.3 | 0.3 | 0.3 | 0.3 | 0.3 | 0.3 | 0.3 | 0.3 | 0.3 | |
| Resistance to swelling | | 65 | 53 | 68 | 65 | 65 | 67 | 72 | 65 | 67 | |
| (mm) | | | | | | | | | | | |
| Fraction of defective resistance | | 0 | 0 | 0 | 0 | 0 | 1 | 2 | 0 | 1 | |
| to formation of cracks | | | | | | | | | | | |
| Fraction of defective adhesion | | 0 | 0 | 0 | 0 | 0 | 0 | 2 | 0 | 0 | |
| (with silver plating) | | | | | | | | | | | |
| Fraction of defective adhesion | | 0 | 0 | 0 | 0 | 0 | 1 | 2 | 0 | 0 | |
| (with chip) | | | | | | | | | | | |
| Fraction of defective adhesion | | 0 | 0 | 0 | 0 | 0 | 0 | 1 | 0 | 0 | |
| (with back face of stage) | | | | | | | | | | | |
| Molding property (property | | 10 | 10 | 10 | 10 | 10 | 10 | 10 | 9 | 9 | |
| of filling package) | | | | | | | | | | | |
| | | 100.0 | 100.0 | 100.0 | 100.0 | 100.0 | 100.0 | 100.0 | 100.0 | 93.20 | |

Notes
#1: Secondary
#2: Primary
#3: Primary + secondary
#4: Ep
#5: Mercapto
*1: Epoxy resin of the tetramethylbisphenol F type
*2: Epoxy resin of the tetramethylbiphenyl type
*3: Epoxy resin of the bisphenol F type represented by formula (IX)
*4: Epoxy resin of the o-cresol novolak type (epoxy equivalent: 194)
*5: Phenol aralkyl resin represented by formula (III)
*6: PN
*6: MEH7860
*8: MEH7851

TABLE 5

| Comparative Example | | 6 | 7 | Note |
|---|---|---|---|---|
| Filler (% by wt) | | 90 | 90 | |
| Silane coupling agent | 1 | 0.4 | 0.4 | #1 |
| (% by wt) | 2 | 0.1 | 0.1 | #2 |
| | 3 | — | — | #3 |
| | 4 | — | — | #4 |
| | 5 | — | — | #5 |
| Epoxy resin | 1 | — | — | *1 |
| (% by wt) | 2 | 4.8 | — | *2 |
| | 3 | — | — | *3 |
| | 4 | — | 5.0 | *4 |
| Curing agent | 1 | — | — | *5 |
| (% by wt) | 2 | — | — | *6 |
| | 3 | 4.1 | 3.9 | *7 |
| | 4 | — | — | *8 |
| Curing accelerator | | 0.1 | 0.1 | |
| (% by wt) | | | | |
| Mold-releasing agent | | 0.2 | 0.2 | |
| (% by wt) | | | | |
| Carbon black (% by wt) | | 0.3 | 0.3 | |
| Resistance to swelling | | 95 | 115 | |
| (mm) | | | | |
| Fraction of defective resistance | | 2 | 20 | |
| to formation of cracks | | | | |
| Fraction of defective adhesion | | 0 | 16 | |
| (with silver plating) | | | | |
| Fraction of defective adhesion | | 0 | 12 | |
| (with chip) | | | | |
| Fraction of defective adhesion | | 2 | 10 | |
| (with back face of stage) | | | | |
| Molding property (property | | 7 | 1 | |
| of filling package) | | | | |
| | | 100.0 | 100.0 | |

Notes
#1: Secondary
#2: Primary
#3: Primary + secondary
#4: Ep
#5: Mercapto
*1: Epoxy resin of the tetramethylbisphenol F type
*2: Epoxy resin of the tetramethylbiphenyl type
*3: Epoxy resin of the bisphenol F type represented by formula (IX)
*4: Epoxy resin of the o-cresol novolak type (epoxy equivalent: 194)
*5: Phenol aralkyl resin represented by formula (III)
*6: PN
*6: MEH7860
*8: MEH7851

As shown in Tables 4 and 5, the epoxy resin compositions of the second aspect of the present invention exhibited excellent adhesion. When phenol compound (b2) represented by formula (III) was contained, the adhesion with the silver plating and the resistance to formation of cracks were further improved, and the molding property was improved from that of compositions using a mixture of homopolymers as the curing agent.

As described above, more excellent properties are exhibited by adding phenol compound (b2). When epoxy resin (a) of the tetramethylbisphenol F type was not used, the resistance to swelling and the adhesion were insufficient.

In contrast, the epoxy resin compositions of the second aspect of the present invention exhibited excellent resistance to swelling, resistance to formation of cracks, adhesion with silver plating and other members and molding property.

The results of the evaluations are shown in Tables 8 to 10.

TABLE 6
Properties of filler (C)

| | Filler (C)*¹ | | | | | |
|---|---|---|---|---|---|---|
| | amorphous | | | amorphous silica | | |
| | silica (c1)*² | | | other than (c1)*³ | | |
| | | median | | | median | |
| | | diameter | amount | | diameter | amount |
| | a/b | (μm) | (% by wt) | a/b | (μ2 m) | (% by wt) |
| Silica (a) | 1.1 | 0.2 | 13 | 1.7 | 13 | 87 |
| Silica (b) | 1.1 | 0.2 | 6 | 1.7 | 13 | 94 |
| Silica (c) | 1.1 | 0.2 | 30 | 1.7 | 13 | 70 |
| Silica (d) | 3.2 | 0.5 | 2 | 1.7 | 13 | 80 |
| | 1.1 | 0.2 | 18 | | | |
| Silica (e) | 1.1 | 0.2 | 2 | 1.7 | 13 | 87 |
| Silica (f) | 1.1 | 0.2 | 35 | 1.7 | 13 | 65 |

Notes
*¹The ratio a/b of a silica shows the average value measured with randomly selected 10 silica particles in electron microscopic pictures of a molded article.
*²Produced by self-combustion of metallic silica at a high temperature in the presence of oxygen; the particle diameter: 0.01 to 1.00 μm
*³The particle diameter exceeding 1.00 μm and 150 μm or smaller (containing no silica particles having a diameter of 1.00 μm or smaller)

TABLE 7
Raw materials used for composition

| Component | Type | Raw material |
|---|---|---|
| Epoxy resin (A) | 1 | epoxy resin of the tetramethylbisphenol F type, |
| | | formula (I) (epoxy equivalent: 192) |
| | 2 | 4,4′-bis(2,3-epoxypropoxy)-3,3′,5,5′-tetramethylbiphenyl |
| | | (epoxy equivalent: 195) |
| | 5 | diglycidyl ether of 1,6-dihydroxynaphthalene (epoxy |
| | | equivalent: 140) |
| Curing agent (B) | 1 | Phenol aralkyl resin, formula (XI) |
| | | (hydroxyl equivalent: 175; ICI viscosity at 150° C.: 0.2 Pa · s) |
| | 2 | Phenyl novolak resin, formula (XII) |
| | | (hydroxyl equivalent: 107; ICI viscosity at 150° C.: 0.2 Pa · s) |
| | 3 | phenol-based compound obtained by random |
| | | copolymerization of repeating units represented by |
| | | formulae (III) and (IV) in relative amounts by |
| | | mole of 1:1 (hydroxyl equivalent: 187; ICI viscosity at |
| | | 150° C.: 0.75 Pa · s; R1 to R8 represent hydrogen atom) |
| Curing accelerator | | triphenylphosphine |
| Silane coupling agent | 1 | N-phenylaminopropyltrimethoxysilane, formula |
| | | (V) |
| | 2 | γ-aminopropyltrimethoxysilane, formula (VI) |
| | 3 | γ-glycidoxypropyltrimethoxysilane, formula (VIII) |
| | 4 | γ-mercaptopropyltrimethoxysilane, formula (IX) |
| Filler (C) | | amorphous spherical silica shown in Table 4 |
| Mold-releasing agent | | carnauba wax |
| Coloring agent | | carbon black |

TABLE 8
Formulation and results of evaluation

| | | Example | | | | | |
|---|---|---|---|---|---|---|---|
| Components | Type | 22 | 23 | 24 | 25 | 26 | 27 |
| Epoxy resin (A) | 1 | 3.4 | 4.8 | 4.8 | 4.8 | 4.8 | 2.9 |
| | 2 | 1.4 | — | — | — | — | 1.2 |
| | 5 | — | — | — | — | — | — |
| Curing agent (B) | 1 | 4.0 | 4.0 | 4.0 | 4.0 | 4.0 | — |
| | 2 | — | — | | — | — | — |
| | 3 | — | — | | — | — | 4.7 |
| Curing accelerator | | 0.1 | 0.1 | 0.1 | 0.1 | 0.1 | 0.1 |
| Filler (C) (amorphous | (a) | 90 | 90 | — | — | — | 90 |
| silica shown in Table | (b) | — | — | 90 | — | — | — |
| 6) | (c) | — | — | — | 90 | — | — |
| | (d) | — | — | — | — | 90 | — |
| | (e) | — | — | — | — | — | — |
| | (f) | — | — | — | — | — | — |
| Silane coupling agent | 1 | 0.6 | 0.6 | 0.6 | 0.6 | 0.6 | 0.6 |
| | 2 | | — | — | — | — | — |
| | 3 | | — | — | — | — | — |
| | 4 | — | — | — | — | — | — |
| Mold-releasing agent | | 0.3 | 0.3 | 0.3 | 0.3 | 0.3 | 0.3 |
| Coloring agent | | 0.2 | 0.2 | 0.2 | 0.2 | 0.2 | 0.2 |
| Resistance to reflow of | | 35 | 30 | 33 | 35 | 39 | 35 |
| solder, swelling of | | (passed) | (passed) | (passed) | (passed) | (passed) | (passed) |
| package (μm) | | | | | | | |
| Resistance to reflow of | | 2 | 1 | 2 | 1 | 1 | 0 |
| solder, fraction of | | (passed) | (passed) | (passed) | (passed) | (passed) | (passed) |
| defective adhesion | | | | | | | |
| (with silver plating) | | | | | | | |
| Molding property, | | 37 | 28 | 40 | 45 | 40 | 42 |
| stage shift (μm) | | (passed) | (passed) | (passed) | (passed) | (passed) | (passed) |

Note:
Numbers for components in the table show the amounts by weight.

TABLE 9
Formulation and results of evaluation

| | | Example | | | | | | | |
|---|---|---|---|---|---|---|---|---|---|
| Components | Type | 28 | 29 | 30 | 31 | 32 | 33 | 34 | 35 |
| Epoxy resin (A) | 1 | 3.4 | 3.4 | 4.8 | 4.8 | 4.8 | 4.8 | 2.9 | 2.9 |
| | 2 | 1.4 | 1.4 | — | — | — | — | 1.2 | 1.2 |
| | 5 | — | — | — | — | — | — | | |
| Curing agent (B) | 1 | 4.0 | 4.0 | 4.0 | 4.0 | 4.0 | 4.0 | | |
| | 3 | — | — | — | — | — | — | 4.7 | 4.7 |
| Curing accelerator | | 0.1 | 0.1 | 0.1 | 0.1 | 0.1 | 0.1 | 0.1 | 0.1 |
| Filler (C) (amorphous | (a) | 90 | 90 | 90 | — | — | — | 90 | 90 |
| silica shown in Table | (b) | — | — | — | 90 | — | — | | |
| 6) | (c) | — | — | — | — | 90 | — | | |
| | (d) | — | — | — | — | — | 90 | | |
| | (e) | — | — | — | — | — | — | | |
| | (f) | — | — | — | — | — | — | | |
| Silane coupling agent | 1 | — | 0.4 | | | — | 0.4 | 0.4 | |
| | 2 | 0.6 | 0.2 | 0.4 | 0.3 | — | 0.2 | 0.2 | 0.3 |
| | 3 | — | — | 0.2 | — | 0.6 | — | | |
| | 4 | — | — | — | 0.3 | — | — | | 0.3 |
| Mold-releasing agent | | 0.3 | 0.3 | 0.3 | 0.3 | 0.3 | 0.3 | 0.3 | 0.3 |
| Coloring agent | | 0.2 | 0.2 | 0.2 | 0.2 | 0.2 | 0.2 | 0.2 | 0.2 |
| Resistance to reflow of | | 33 | 30 | 39 | 35 | 39 | 30 | 30 | 30 |
| solder, swelling of | | (p) | (p) | (p) | (p) | (p) | (p) | (p) | (p) |
| package (μm) | | | | | | | | | |
| Resistance to reflow of | | 0 | 0 | 1 | 0 | 1 | 0 | 0 | 0 |
| solder, fraction of | | (p) | (p) | (p) | (p) | (p) | (p) | (p) | (p) |
| defective adhesion | | | | | | | | | |
| (with silver plating) | | | | | | | | | |
| Molding property, | | 40 | 30 | 42 | 38 | 40 | 32 | 33 | 37 |
| stage shift (μm) | | (p) | (p) | (p) | (p) | (p) | (p) | (p) | (p) |

Note:
Numbers for components in the table show the amounts by weight;
(p) means (passed).

TABLE 10
Formulation and results of evaluation

| | | Comparative Example | | | | |
|---|---|---|---|---|---|---|
| Components | Type | 8 | 9 | 10 | 11 | 12 |
| Epoxy resin (A) | 1 | 4.8 | 4.8 | 6.5 | 1.5 | — |
| | 2 | — | — | — | — | — |
| | 3 | — | — | — | — | 4.1 |
| Curing agent (B) | 1 | 4.0 | 4.0 | 5.3 | 1.3 | 4.7 |
| | 2 | — | — | — | — | — |
| | 3 | — | — | — | — | — |
| Curing | | 0.1 | 0.1 | 0.1 | 0.1 | 0.1 |
| accelerator | | | | | | |
| Filler (C) | (a) | — | — | — | 96 | 90 |
| (amorphous silica | (b) | — | — | — | — | — |
| shown in | (c) | — | — | — | — | — |
| Table 6) | (d) | — | — | — | — | — |
| | (e) | 90 | | — | — | — |
| | (f) | — | 90 | 87 | — | — |
| Silane coupling | 1 | 0.6 | 0.6 | 0.6 | 0.6 | 0.6 |
| agent | 2 | | — | — | — | — |
| | 3 | | — | — | — | — |
| | 4 | — | — | — | — | — |
| Mold-releasing | | 0.3 | 0.3 | 0.3 | 0.3 | 0.3 |
| agent | | | | | | |
| Coloring agent | | 0.2 | 0.2 | 0.2 | 0.2 | 0.2 |
| Resistance to | | 82 | 87 | 110 | 85 | 95 |
| reflow of solder, | | (failed) | (failed) | (failed) | (failed) | (failed) |
| swelling of | | | | | | |
| package (μm) | | | | | | |
| Resistance to | | 2 | 6 | 5 | 8 | 2 |
| reflow of solder, | | (passed) | (failed) | (failed) | (failed) | (passed) |
| fraction of | | | | | | |
| defective | | | | | | |
| adhesion | | | | | | |
| (with silver | | | | | | |
| plating) | | | | | | |
| Molding property, | | 58 | 115 | 40 | 97 | 39 |
| stage shift (μm) | | (failed) | (failed) | (passed) | (failed) | (passed) |

Note:
Numbers for components in the table show the amounts by weight.

As shown in Tables 8 to 10, the epoxy resin compositions of the third aspect of the present invention exhibited excellent resistance to the solder reflow and molding property (stage shift) when the content of amorphous silica (c1) having the particle diameter in the range of 0.01 to 1.00 mm in filler (C) was in the range of 5 to 30% by weight as shown in Examples 22 to 32. In contrast, the excellent resistance to solder reflow and the excellent molding property (stage shift) could not be achieved simultaneously when the above content was outside the range of 5 to 30% by weight or when epoxy resin (a) of the bisphenol F type expressed by formula (I) was not contained as shown in Comparative Examples 12 to 17.

Industrial Applicability

The epoxy resin composition of the present invention can be advantageously used as the material for efficiently sealing electronic circuit members such as semiconductor devices. The semiconductor devices sealed with the epoxy resin composition can be utilized as electronic circuit members of computers.

1-14. (canceled)

15. An epoxy resin composition which comprises epoxy resin (A), curing agent (B), filler (C) and silane coupling agent (D), wherein epoxy resin (A) comprises epoxy resin (a) of a tetramethylbisphenol F type expressed by formula (I): 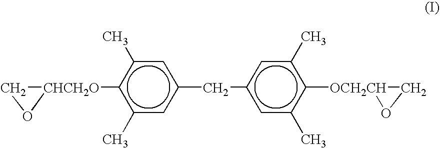
and silane coupling agent (D) comprises aminosilane coupling agent (d1) having primary amino group.

16. An epoxy resin composition according to claim 15, wherein silane coupling agent (D) comprises aminosilane coupling agent (d1) having primary amino group and silane coupling agent (d2) other than aminosilane coupling agent (d1) having primary amino group.

17. An epoxy resin composition according to claim 16, wherein silane coupling agent (d2) comprises at least one coupling agent selected from the group consisting of aminosilane coupling agents having no primary amino group but having secondary amino group and mercaptosilane coupling agents.

18. An epoxy resin composition according to claim 15, wherein curing agent (B) comprises phenol aralkyl resin (b1) represented by formula (II): 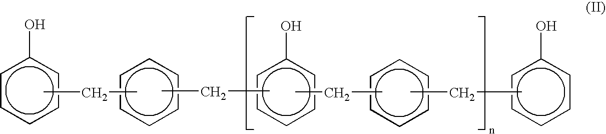
wherein n represents 0 or an integer of 1 or greater.

19. An epoxy resin composition according to claim 16, wherein curing agent (B) comprises phenol aralkyl resin (b1) represented by formula (II): 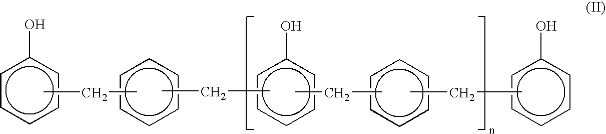
wherein n represents 0 or an integer of 1 or greater.

20. An epoxy resin composition according to claim 17, wherein curing agent (B) comprises phenol aralkyl resin (b1) represented by formula (II): 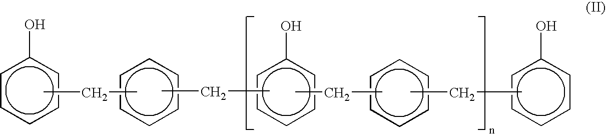
wherein n represents 0 or an integer of 1 or greater.

21. An epoxy resin composition which comprises epoxy resin (A), curing agent (B) and filler (C), wherein epoxy resin (A) comprises epoxy resin (a) of a tetramethylbisphenol F type, and curing agent (B) comprises phenol compound (b2) having a repeating unit structure represented by formula (III): 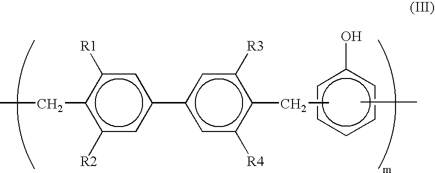
wherein m represents an integer of 1 or greater, and a repeating unit structure represented by formula (IV): 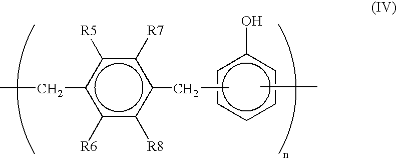
wherein R5 to R8 represent a hydrogen atom or a methyl group and n represents an integer of 1 or greater.

22. An epoxy resin composition according to claim 21, which comprises silane coupling agent (D) comprising aminosilane coupling agent (d1) having primary amino group.

23. An epoxy resin composition according to claim 22, wherein silane coupling agent (D) comprises aminosilane coupling agent (d1) having primary amino group and silane coupling agent (d2) other than aminosilane coupling agent (d1) having primary amino group.

24. An epoxy resin composition according to claim 23, wherein silane coupling agent (d2) comprises at least one coupling agent selected from the group consisting of aminosilane coupling agents having no primary amino group but having secondary amino group and mercaptosilane coupling agents.

25. An epoxy resin composition which comprises epoxy resin (A), curing agent (B) and filler (C), wherein epoxy resin (A) comprises epoxy resin (a) of a tetramethylbisphenol F type, a content of filler (C) is 80 to 95% by weight based on an amount of an entire resin composition, and filler (C) comprises 5 to 30% by weight of amorphous silica (c1) having a particle diameter in a range of 0.01 to 1.00 μm.

26. An epoxy resin composition according to claim 25, wherein 90% by weight of particles constituting amorphous silica (c1) are spherical silica having a ratio (a/b) of a length of a major axis a to a length of a minor axis b of 2 or smaller.

27. An epoxy resin composition according to claim 26, which comprises silane coupling agent (D) comprising aminosilane coupling agent (d1) having primary amino group.

28. An epoxy resin composition according to claim 26, which comprises a silane coupling agent (D) comprising aminosilane coupling agent (d1) having primary amino group and silane coupling agent (d2) other than aminosilane coupling agent (d1) having primary amino group.

29. An epoxy resin composition according to claim 28, wherein silane coupling agent (d2) comprises at least one coupling agent selected from a group consisting of aminosilane coupling agents having no primary amino group but having secondary amino group and mercaptosilane coupling agents.

30. A semiconductor device which is sealed with an epoxy resin composition described in claim 15.

31. A semiconductor device which is sealed with an epoxy resin composition described in claim 21.

32. A semiconductor device which is sealed with an epoxy resin composition described in claim 25.

33. A method of sealing a semiconductor device comprising providing a member having a semiconductor fixed to a substrate, molding over the semiconductor the epoxy resin composition of claim 15 and curing the composition, thereby sealing the semiconductor.

34. A method of sealing a semiconductor device comprising providing a member having a semiconductor fixed to a substrate, molding over the semiconductor the epoxy resin composition of claim 21 and curing the composition, thereby sealing the semiconductor.

35. A method of sealing a semiconductor device comprising providing a member having a semiconductor fixed to a substrate, molding over the semiconductor the epoxy resin composition of claim 25 and curing the composition, thereby sealing the semiconductor.
